(19) United States
(12) Patent Application Publication
(10) Pub. No.: US 2020/0287104 A1
(43) Pub. Date: Sep. 10, 2020

(54) PACKAGE

(71) Applicant: Lextar Electronics Corporation, Hsinchu (TW)

(72) Inventors: Shiou-Yi KUO, Hsinchu (TW); Jian-Chin LIANG, Hsinchu (TW); Yu-Chun LEE, Hsinchu (TW); Fu-Hsin CHEN, Hsinchu (TW); Jo-Hsiang CHEN, Hsinchu (TW); Chien-Nan YEH, Hsinchu (TW)

(21) Appl. No.: 16/809,531

(22) Filed: Mar. 4, 2020

(30) Foreign Application Priority Data
Mar. 6, 2019 (CN) 201910167401.9

(51) Int. Cl. H01L 33/50; H01L 25/075; H01L 33/62

(52) U.S. Cl. CPC H01L 33/505; H01L 33/62; H01L 25/0753

(57) ABSTRACT

A package includes a substrate and a plurality of light-emitting chips. The substrate has a top surface. The light-emitting chips are disposed on the top surface of the substrate, in which a sum of the vertical projection areas of the light-emitting chips on the top surface of the substrate is less than 5% of an area of the top surface of the substrate.

### CROSS-REFERENCE TO RELATED APPLICATION

This application claims priority to China Application Serial Number 201910167401.9, filed Mar. 6, 2019, which is herein incorporated by reference in its entirety.

### BACKGROUND

### Field of Invention

The present invention relates to a package.

### Description of Related Art

Light emitting diodes are devices that emit light when a forward current flows through a semiconductor P-N junction. The light emitting diodes may be made of III-V semiconductor materials, such as GaAs or GaN. Recently, due to the advances in the semiconductor epitaxial growth technique and the light emitting device processes, light emitting diodes with excellent converting efficiency have been developed. The light emitting diodes are widely used in various fields. However, due to the size of the conventional light emitting diodes, it is easy to be observed in display devices. Therefore, a new package is needed to address the problem mentioned above.

### SUMMARY

The invention provides a package. The package includes a substrate and a plurality of light emitting chips. The substrate has a top surface. The light emitting chips are disposed on the top surface of the substrate. A sum of vertical projection areas of the light emitting chips on the top surface is less than 5% of an area of the top surface.

In accordance with an embodiment of the present invention, each of the light emitting chips is configured to emit a light with a wavelength different from each other.

In accordance with an embodiment of the present invention, the package further includes a wavelength conversion layer covering one of the light emitting chips solely.

In accordance with an embodiment of the present invention, the package further includes a driver chip disposed on the substrate and electrically connected with the light emitting chips.

In accordance with an embodiment of the present invention, each of the light emitting chips includes a pair of first electrical contacts, the substrate includes a plurality of pairs of second electrical contacts disposed on the top surface of the substrate, and each pair of the first electrical contacts are electrically connected with each pair of the second electrical contacts respectively.

In accordance with an embodiment of the present invention, the pair of the first electrical contacts of each light emitting chip are disposed at a same side of said each light emitting chip.

In accordance with an embodiment of the present invention, the pair of the first electrical contacts of each light emitting chip are disposed at opposite sides of said each light emitting chip.

The invention also provides a package. The package includes a substrate, a plurality of light emitting chips and a package layer. The substrate has a top surface and a bottom surface opposite to the top surface. The light emitting chips are disposed on the top surface of the substrate, and each of the light emitting chips has an upper surface. The package layer covers the top surface of the substrate and the upper surface of each of the light emitting chips. The package layer has a top surface. A ratio of a distance between the top surface of the substrate and the upper surface of each of the light emitting chips to a distance between the bottom surface of the substrate and the top surface of the package layer is less than 0.1.

In accordance with an embodiment of the present invention, a distance between the upper surface of each of the light emitting chips and the top surface of the package layer is greater than 5 times of a distance between the top surface of the substrate and the upper surface of each of the light emitting chips.

In accordance with an embodiment of the present invention, the package further includes a driver chip disposed on the substrate and electrically connected with the light emitting chips.

In accordance with an embodiment of the present invention, a distance between the top surface of the substrate and the upper surface of each of the light emitting chips is less than 10 μm.

The technical solution of the present invention may improve the user experience and reduce the probability of the light emitting chips being observed by users. In addition, the package herein may also increase the current density, such that the luminous efficiency of the light emitting chips is also increased. Besides, since the vertical projection area of the light emitting chips on the substrate is relatively small, the cost can be reduced and the contrast can be improved. The black area is also increased.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 illustrates a top view of a package 100 according to an embodiment of the present invention;

FIG. 2 illustrates a cross-section view of the package 100 according to an embodiment of the present invention;

FIG. 3 illustrates a cross-section view of a package 100a according to an embodiment of the present invention;

FIG. 4 illustrates a cross-section view of an package 200 according to an embodiment of the present invention; and

FIG. 5 illustrates a cross-section view of a package 300 according to an embodiment of the present invention.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over a second feature in the description that follows may include embodiments in which the first and second features are formed in direct contact, and may also include embodiments in which additional features are disposed between the first and second features, such that the first and second features are not in direct contact.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

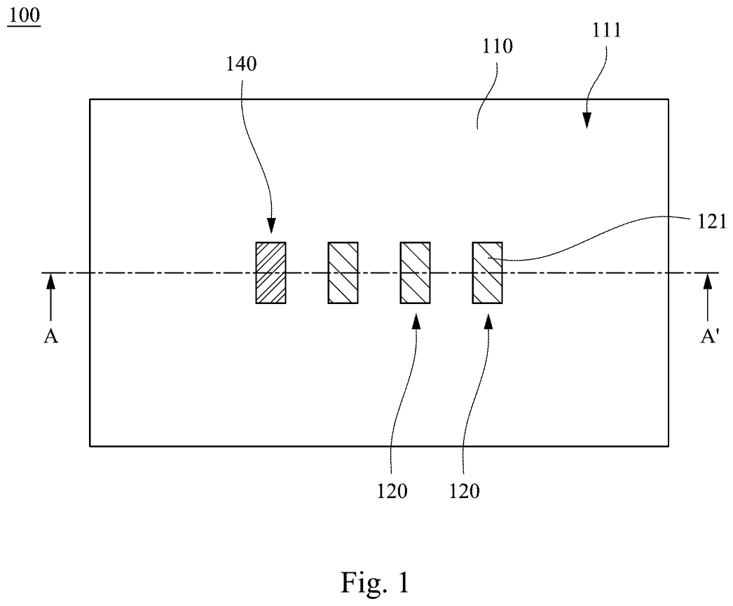

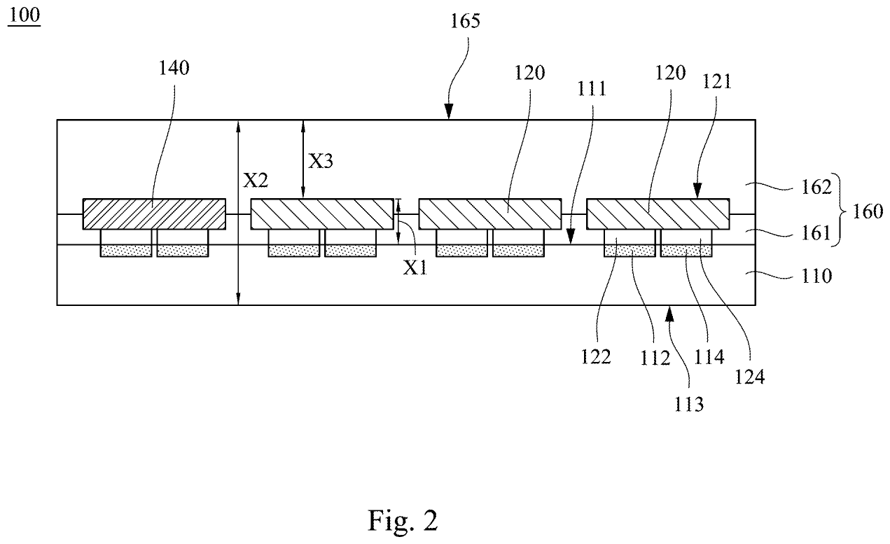

FIG. 1 illustrates a top view of a package 100 according to an embodiment of the present invention. FIG. 2 illustrates a cross-section view along a line AA′ of the package 100. Referring to FIG. 1, the package 100 includes a substrate 110 and a plurality of light emitting chips 120. In some examples, the substrate 110 may be a rectangle in the top view, such as a square. In certain examples, the substrate 110 has a side length ranging from 250 μm to 1200 μm, such as 250 μm, 500 μm, 750 μm, 1000 μm or 1200 μm.

The light emitting chips 120 are disposed on a top surface 111 of the substrate 110. The sum of vertical projection areas of light emitting chips 120 on the top surface 111 is less than 5% of an area of the top surface 111 in the top view. Further, in the present invention, the area of each light emitting chip 120 is decreased such that the sum of the vertical projection areas of the light emitting chips 120 on the top surface 111 is less than 5% of the area of the top surface 111. If the sum of vertical projection areas of the light emitting chips 120 on the top surface 111 is greater than 5% of the area of the top surface 111, the light emitting chips 120 may be easily observed by users, thus affecting the user experience. In other words, the technical solution of the present invention may improve the user experience and reduce the probability of the light emitting chips 120 being observed by users. In addition, the maximum luminous efficiency of the light emitting chips 120, such as light emitting diode, is achieved only in a specific current density range. However, in general, the current density is less than the above-mentioned range, and the light emitting chips can not achieve the maximum luminous efficiency. The light emitting chips 120 with small area, which may also increase the current density, is used in the present invention such that the current density falls into the range mentioned above. The luminous efficiency of the light emitting chips 120 is therefore increased.

In some examples, the package 100 further includes a driver chip 140 disposed on the substrate 110 and electrically connected with each of the light emitting chips 120. The driver chip 140 is configured to control the light emitting chips 120 such that the brightness of the light emitting chips 120 is controllable.

In some examples, the light emitting chips 120 may be light emitting diodes (LED). In further examples, the light emitting chips 120 may be micro LEDs. In certain examples, the light emitting chips 120 emit lights having different wavelengths. For example, each light emitting chip 120 may emit primary color light, such as red light, green light or blue light. Hence, the light emitting chip 120 may be an element of a display device to display a desired color. In addition, in some examples, multiple light emitting chips 120 may constitute a pixel unit of the display device.

Please refer to FIG. 2, each light emitting chip 120 includes a pair of first electrical contacts 122, 124, and the substrate 110 includes a pair of second electrical contacts 112, 114. In some embodiments, the substrate 110 includes a plurality of pairs of second electrical contacts 112, 114. The first electrical contacts 122, 124 are respectively connected with the second electrical contacts 112, 114. In certain embodiments, each pair of the first electrical contacts 122, 124 are respectively connected with each pair of the second electrical contacts 112, 114. In some examples, the second electrical contacts 112, 114 are disposed on the top surface 111 of the substrate 110. Therefore, the second electrical contacts 112, 114 are in direct contact with the first electrical contacts 122, 124, respectively.

In another embodiment, the package 100 further includes a package layer 160. The package layer 160 covers the top surface 111 of the substrate 110 and an upper surface 121 of each light emitting chip 120. In some examples, a ratio of a distance X1 between the top surface 111 of the substrate 110 and the upper surface 121 of each light emitting chip 120 to a distance X2 between a bottom surface 113 of the substrate 110 and a top surface 165 of the package layer 160 is less than 0.1 (X1/X2<0.1).

In some examples, the package layer 160 includes a first insulating layer 161 and a second insulating layer 162. The first electrical contacts 122 of the light emitting chips 120 are surrounded and covered by the first insulating layer 161. The second insulating layer 162 is disposed on the first insulating layer 161 and covers the light emitting chips 120. The first insulating layer 161 may be used as an insulator between adjacent ones of the first electrical contacts 122, 124. The package layer 160 having a two-layer structure may better bond the light emitting chips 120 to the substrate 110. In detail, the first insulating layer 161 may completely fill the gap between the first electrical contacts 122, 124, and the second insulating layer 162 may completely cover the first insulating layer 161 and the light emitting chips 120.

Besides, in some examples, a distance X3 between the upper surface 121 of each of the light emitting chips 120 and the top surface 165 of the package layer 160 is greater than 5 times of the distance X1 between the top surface 111 of the substrate 110 and the upper surface 121 of each of the light emitting chips 120. In some examples, the distance X1 between the top surface 111 of the substrate 110 and the upper surface 121 of each of the light emitting chips 120 is less than 10 μm, such as 8 μm, 7 μm, 6 μm or 5 μm.

The light emitting chips 120 disposed on the substrate 110 herein have a specific thickness. As a result, the total thickness and the size of the package are decreased so as to decrease the cost. Besides, the present invention may also be applied to miniaturized display devices.

As mentioned above, the light emitting chips 120 may emit lights with different wavelengths. Thus, in some examples, the light emitting chips 120 may be different light emitting diodes, such as a red light emitting diode, a green light emitting diode and a blue light emitting diode.

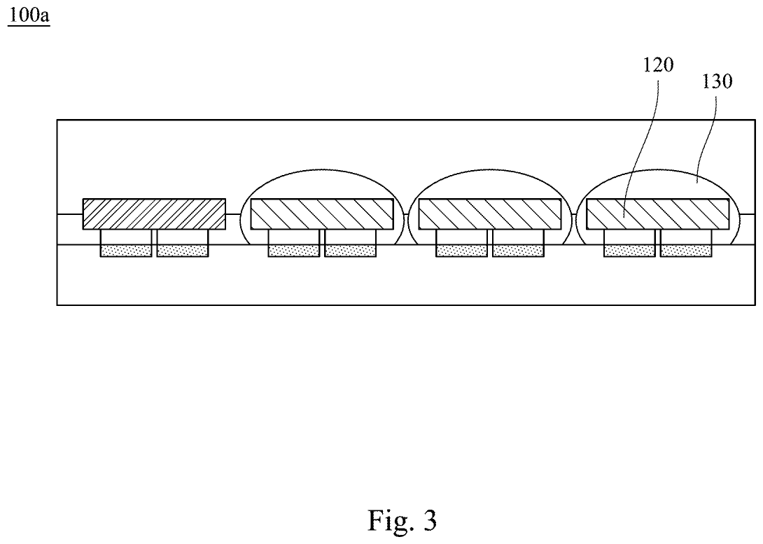

In addition, please refer to FIG. 3, which illustrates a cross-section view of a package 100a according to an embodiment of the present invention. The package 100a further includes a wavelength conversion layer 130 covering at least one of the light emitting chips 120. In some embodiments, the wavelength conversion layer 130 covers one of the light emitting chips 120 solely. The light emitting chips 120 are the same-typed light emitting diodes, therefore emit lights with the same wavelength. Since the lights emitted from the light emitting chips 120 pass through the different wavelength conversion layers 130, the lights become different colors (different wavelengths). In some examples, the different wavelength conversion layers 130 respectively cover the light emitting chips 120.

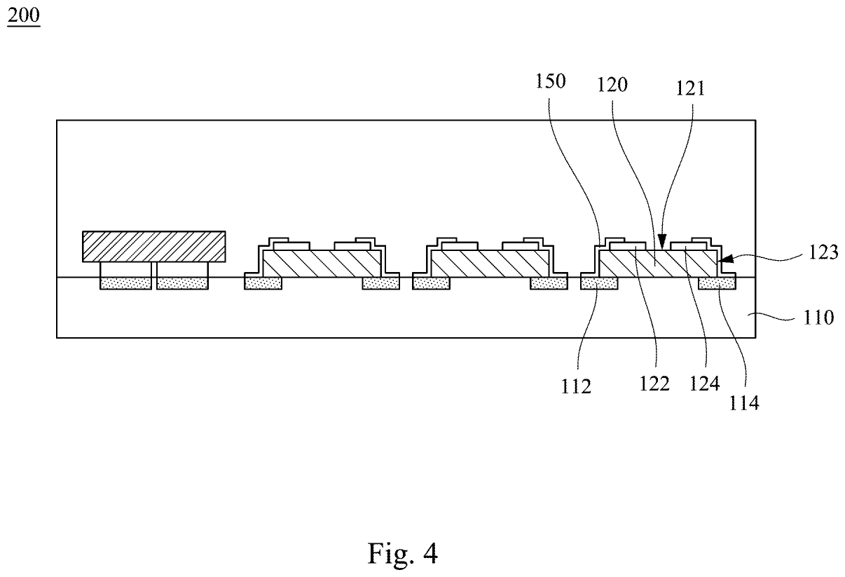

The present invention also provides a package 200. Please refer to FIG. 4, which illustrates a cross-section view of a package 200 according to an embodiment of the present invention. Different from the package 100, the first electrical contacts 122, 124 of the light emitting chip 120 of the package 200 are disposed on the upper surface 121 of the light emitting chip 120. In some examples, the package 200 includes a conductive layer 150 extending from the first electrical contacts 122, 124 to the second electrical contacts 112, 114 of the substrate 110. Further, the conductive layer 150 extends along a sidewall 123 of the light emitting chip 120, and each of the light emitting chips 120 is electrically connected with the substrate 110 through the conductive layer 150.

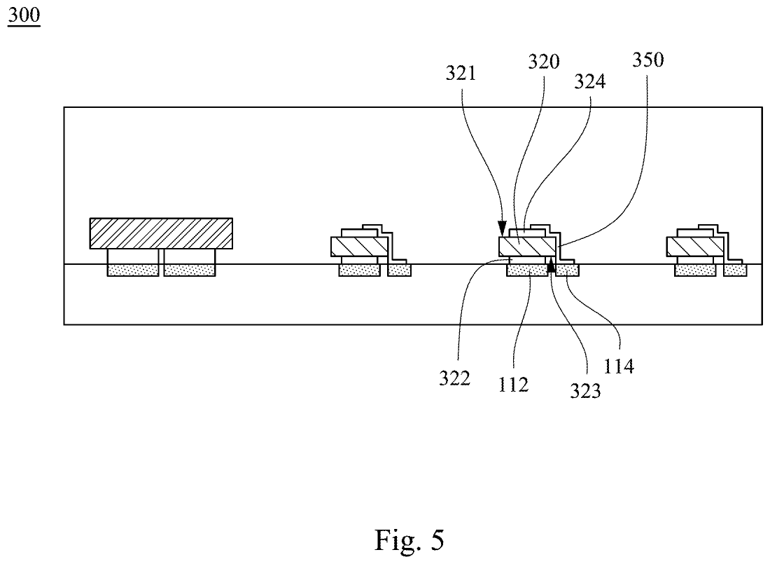

Please refer to FIG. 5, which illustrates a cross-section view of a package 300 according to an embodiment of the present invention. Different from the package 100 and the package 200, first electrical contacts 322, 324 of a light emitting chip 320 of the package 300 are disposed at the opposite sides of the light emitting chip 320. In detail, the first electrical contact 322 is disposed on a bottom surface 323 of the light emitting chip 320, and the first electrical contact 324 is disposed on an upper surface 321 of the light emitting chip 320. Hence, in the present example, the first electrical contact 322 of light emitting chip 320 is in direct contact with the second electrical contact 112 of the substrate 110, and the first electrical contact 324 is electrically connected with the second electrical contact 114 through the conductive layer 350.

Therefore, in some examples of the present invention, such as the examples illustrated in FIGS. 2-4, the first electrical contacts 122,124 of the light emitting chip 120 are disposed at the same side of the light emitting chip 120. In other examples, such as the example illustrated in FIG. 5, the first electrical contacts 322, 324 of the light emitting chip 320 may be disposed at the opposite sides of the light emitting chip 320. The aforementioned examples are merely exemplary and are not intended to be limited. Any suitable packages can be used, depending on demands.

The technical solution of the present invention may improve the user experience and reduce the probability of the light emitting chips being observed by users. In addition, the package herein may also increase the current density, such that the luminous efficiency of the light emitting chips is also increased. Besides, since the vertical projection area on the substrate of the light emitting chip is relatively small, the cost can be reduced and the contrast can be improved. The black area is also increased.

Although the present invention has been described in considerable detail with reference to certain embodiments thereof, other embodiments are possible. Therefore, the spirit and scope of the appended claims should not be limited to the description of the embodiments contained herein. It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A package, comprising:
a substrate having a top surface; and
a plurality of light emitting chips disposed on the top surface of the substrate, wherein a sum of vertical projection areas of the light emitting chips on the top surface is less than 5% of an area of the top surface.

2. The package of claim 1, wherein each of the light emitting chips is configured to emit a light with a wavelength different from each other.

3. The package of claim 1, further comprising a wavelength conversion layer covering one of the light emitting chips solely.

4. The package of claim 1, further comprising a driver chip disposed on the substrate and electrically connected with the light emitting chips.

5. The package of claim 1, wherein each of the light emitting chips comprises a pair of first electrical contacts, the substrate comprises a plurality of pairs of second electrical contacts disposed on the top surface of the substrate, and each pair of the first electrical contacts are electrically connected with each pair of the second electrical contacts respectively.

6. The package of claim 5, wherein the pair of the first electrical contacts of each light emitting chip are disposed at a same side of said each light emitting chip.

7. The package of claim 5, wherein the pair of the first electrical contacts of each light emitting chip are disposed at opposite sides of said each light emitting chip.

8. A package, comprising:
a substrate having a top surface and a bottom surface opposite to the top surface;
a plurality of light emitting chips disposed on the top surface of the substrate, wherein each of the light emitting chips has an upper surface; and
a package layer covering the top surface of the substrate and the upper surface of each of the light emitting chips, wherein the package layer has a top surface, a ratio of a distance between the top surface of the substrate and the upper surface of each of the light emitting chips to a distance between the bottom surface of the substrate and the top surface of the package layer is less than 0.1.

9. The package of claim 8, wherein a distance between the upper surface of each of the light emitting chips and the top surface of the package layer is greater than 5 times of the distance between the top surface of the substrate and the upper surface of each of the light emitting chips.

10. The package of claim 8, further comprising a driver chip disposed on the substrate and electrically connected with the light emitting chips.

11. The package of claim 8, wherein a distance between the top surface of the substrate and the upper surface of each of the light emitting chips is less than 10 μm.
